(19) United States
(12) Patent Application Publication
(10) Pub. No.: US 2010/0188270 A1
(43) Pub. Date: Jul. 29, 2010

(54) OPTICAL INTERRUPTING INTERFACE

(75) Inventor: Jeffrey Brian Sampsell, Pueblo West, CO (US)

Correspondence Address: Weaver Austin Villeneuve & Sampson LLP - QUAL, P.O. Box 70250, Oakland, CA, 94612-0250, US

(73) Assignee: Qualcomm MEMS Technologies, Inc.

(21) Appl. No.: 12/361,416

(22) Filed: Jan. 28, 2009

(51) Int. Cl. H03K 17/94; G01N 21/00; G02B 6/12; C03C 25/10

(52) U.S. Cl. 341/31; 356/432; 385/14; 65/430

(57) ABSTRACT

Improved user interface methods and devices are provided. Some such devices are configured to detect a user's touch according to a localized diminution and/or interruption of guided optical signals. The devices may be configured for guiding light in a piece-wise contiguous array of optical blocks disposed on a flexible substrate. Alternatively, or additionally, the devices may be configured for guiding light along non-continuous optical fibers on a flexible substrate. These basic structures, or comparable structures, may be used to implement a wide range of tactile user interfaces.

### FIELD OF THE INVENTION

This application relates generally to user interfaces.

### BACKGROUND OF THE INVENTION

There are various types of user interfaces in use today, including keyboards, touch screens and the like. Touch-based user interfaces are most commonly implemented through electronic contacting or capacitance sensing. More advanced user interfaces have been suggested, such as those responsive to voice, gesture, brain waves, eye movement, etc. However, none of these interfaces has proven to be entirely satisfactory. Some are difficult to implement and/or to learn. Many are expensive. Therefore, it would be desirable to provide improved user interfaces.

### SUMMARY

Improved user interface methods and devices are provided. Some such devices are configured to detect a user's touch according to a localized diminution and/or interruption of guided optical signals. Accordingly, such devices are sometimes referred to herein as “optical interrupting interfaces” or the like. For example, an optical interrupting interface may be configured for guiding light in a plurality of discontinuous waveguide features disposed on a flexible substrate. The plurality of discontinuous waveguide features may, for example, comprise a piece-wise contiguous array of optical blocks. Alternatively, or additionally, the optical interrupting interface may be configured for guiding light along non-continuous optical fibers on a flexible substrate. These basic structures, or comparable structures, may be used to implement a wide range of tactile user interfaces. Devices that incorporate optical interrupting interfaces and methods of manufacturing optical interrupting interfaces are also described herein.

Some embodiments described herein provide an apparatus that may include the following elements: a flexible layer; a light-transmitting layer affixed to the flexible layer, the light-transmitting layer comprising a plurality of discontinuous waveguide features; at least one light source configured to provide light to the light-transmitting layer; at least one receiver configured to receive light via the light-transmitting layer; and a logic system configured to determine an area of the light-transmitting layer having diminished light transmission between at least two adjacent waveguide features. Some such embodiments include a plurality of light sources configured to provide light to the light-transmitting layer and/or a plurality of receivers configured to receive light via the light-transmitting layer.

The area of the light-transmitting layer having diminished light transmission may comprise a waveguide feature that has been temporarily rotated with respect to an adjacent waveguide feature. For example, the waveguide feature may have been temporarily rotated in response to a force applied to the flexible layer.

Related embodiments may provide a user interface comprising such an apparatus. Some such embodiments may provide a touch screen, a keyboard, etc. Portable devices including such user interfaces are described herein.

In some such embodiments, the plurality of light sources may be disposed proximate a first edge of the light-transmitting layer. The plurality of receivers may be disposed proximate a second edge of the light-transmitting layer.

Some such portable devices may include a first user interface disposed along a first side of the portable device and/or a second user interface is disposed along a second side of the portable device. In some instances, the second side may be opposite the first side.

The logic system may be further configured to determine at least one portion of the portable device to which a compressional force is being applied. Alternatively, or additionally, the logic system may be further configured to determine a magnitude of the force and/or a time interval during which the force is applied. The logic system may be configured to associate the force, the magnitude and/or the time interval with a predetermined user input.

Methods of forming a waveguide are provided herein. Some such methods include the following steps: forming discontinuities in a waveguide layer to produce a layer of discontinuous waveguide features; affixing the first layer to a second layer of flexible material; configuring at least one light source to provide light to the layer of discontinuous waveguide features; and configuring at least one receiver to receive light via the layer of discontinuous waveguide features.

The method may further include the steps of configuring a logic system to do the following: control the light source(s); receive signals from the receiver(s); and make a correspondence between forces applied to the flexible layer and changes of light transmission in the layer of discontinuous waveguide features. According to some such methods, the step of configuring at least one light source may comprise configuring a plurality of light sources to provide light to the layer of discontinuous waveguide features and the controlling step may comprise controlling the plurality of light sources. Similarly, the step of configuring at least one receiver may comprise configuring a plurality of receivers to provide light to the layer of discontinuous waveguide features. The receiving step may comprise receiving signals from the plurality of receivers.

The forming process may comprise embossing, pressing and/or stamping. The forming, affixing and/or cladding may be performed as part of a roll-to-roll process. The forming process may comprise forming linear discontinuities and/or forming a plurality of discontinuous polygons. The forming process may involve forming offsets in at least some of the linear discontinuities. The forming process may involve dicing the discontinuities into the first layer. The affixing process may or may not be performed prior to the forming process.

Alternative embodiments provide an apparatus that may include the following elements: a flexible layer; a light-transmitting layer affixed to the flexible layer, the light-transmitting layer comprising a plurality of discontinuous waveguide features; at least one light source configured to provide light to the light-transmitting layer; at least one receiver configured to receive light via the light-transmitting layer; and a logic system configured to determine an area of the light-transmitting layer wherein a waveguide feature has been temporarily rotated with respect to an adjacent waveguide feature. The waveguide feature may, for example, have been temporarily rotated by a force that has been applied to the flexible layer. Some such embodiments include a plurality of light sources configured to provide light to the light-transmitting layer and/or a plurality of receivers configured to receive light via the light-transmitting layer.

In some such embodiments, the waveguide features may be polygonal in shape. For example, the waveguide features may be rectangular and/or trapezoidal in shape.

Alternative implementations provide a portable device that may include the following elements: a flexible layer; a light-transmitting layer affixed to the flexible layer, the light-transmitting layer comprising a plurality of discontinuous waveguide features; at least one light source configured to provide light to the light-transmitting layer; at least one receiver configured to receive light via the light-transmitting layer; a logic system configured to determine an area of the light-transmitting layer having diminished light transmission between at least two adjacent waveguide features; and at least one key disposed on a first surface of the portable device and configured to cause diminished light transmission between at least two adjacent waveguide features when depressed. The portable device may include at least one communication interface. Some such devices include a plurality of light sources configured to provide light to the light-transmitting layer and/or a plurality of receivers configured to receive light via the light-transmitting layer.

In some instances, the first surface may be an outer surface of the portable device. The portable device may also include a user interface disposed on a second surface of the portable device. In some implementations, at least a portion of the second surface is on an opposite side from the first surface. The user interface may be configured to cause diminished light transmission between at least two adjacent waveguide features when depressed.

The second surface may be an inner surface of the portable device. In some instances, the second surface may be accessible only when the portable device is in an open position. The logic device may be configured to apply a first rule set to interpret light transmission of the light-transmitting layer when the portable device is in the open position. The logic device may be configured to apply a second rule set to interpret light transmission of the light-transmitting layer when the portable device is in a closed position.

These and other methods of the invention may be implemented by various types of hardware, software, firmware, etc. For example, some features of the invention may be implemented, at least in part, by computer programs embodied in machine-readable media. The computer programs may, for example, include instructions for determining the location of a user's touch according to disrupted optical transmission. Other programs may associate touch and/or gesture data with predetermined user commands and/or control a device according to the commands. Still other programs may include instructions for controlling one or more devices to fabricate optical interrupting interfaces.

### BRIEF DESCRIPTION OF THE DRAWINGS

FIG. 1A depicts a simplified version of an optical interrupting interface that comprises adjacent waveguide features on a flexible substrate.

FIG. 1B depicts the optical interrupting interface of FIG. 1A after a force 130 has been applied to the flexible substrate.

FIG. 2A depicts a simplified version of an optical interrupting interface that comprises a plurality of adjacent waveguide features on a flexible substrate.

FIG. 2B depicts the optical interrupting interface of FIG. 2A after a force 130 has been applied to the flexible substrate.

FIGS. 3A-3E provide examples of how waveguide features may be arranged on a flexible substrate.

FIG. 4 illustrates a portable device that includes an optical interrupting interface.

FIG. 5 is a schematic diagram that depicts components of one example of a device that incorporates an optical interrupting interface.

FIG. 6A illustrates a key pad that may include an optical interrupting interface.

FIGS. 6B and 6C illustrate alternative embodiments that may be useful in a clamshell or flip-phone type configuration.

FIG. 7 is a flow chart that outlines some methods of fabricating optical interrupting interfaces.

### DETAILED DESCRIPTION

While the present invention will be described with reference to a few specific embodiments, the description and specific embodiments are merely illustrative of the invention and are not to be construed as limiting the invention. Various modifications can be made to the described embodiments without departing from the true spirit and scope of the invention as defined by the appended claims. For example, the steps of methods shown and described herein are not necessarily performed in the order indicated. It should also be understood that the methods of the invention may include more or fewer steps than are indicated. In some implementations, steps described herein as separate steps may be combined. Conversely, what may be described herein as a single step may be implemented in multiple steps.

Similarly, device functionality may be apportioned by grouping or dividing tasks in any convenient fashion. For example, when steps are described herein as being performed by a single device (e.g., by a single logic device), the steps may alternatively be performed by multiple devices and vice versa.

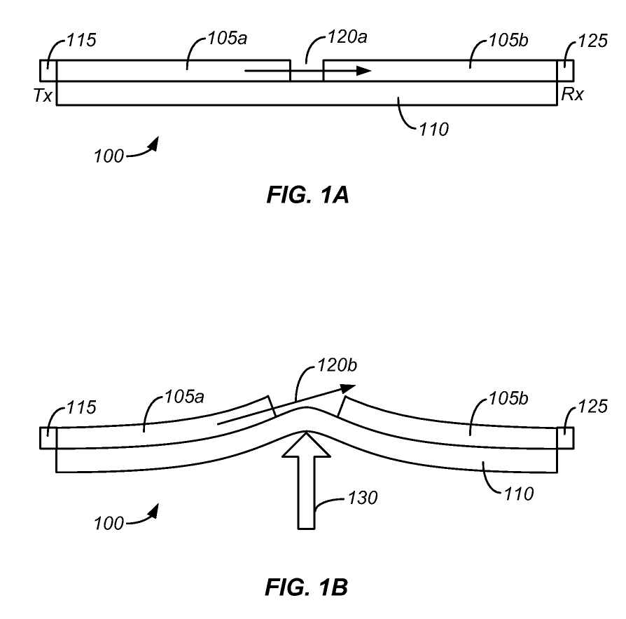

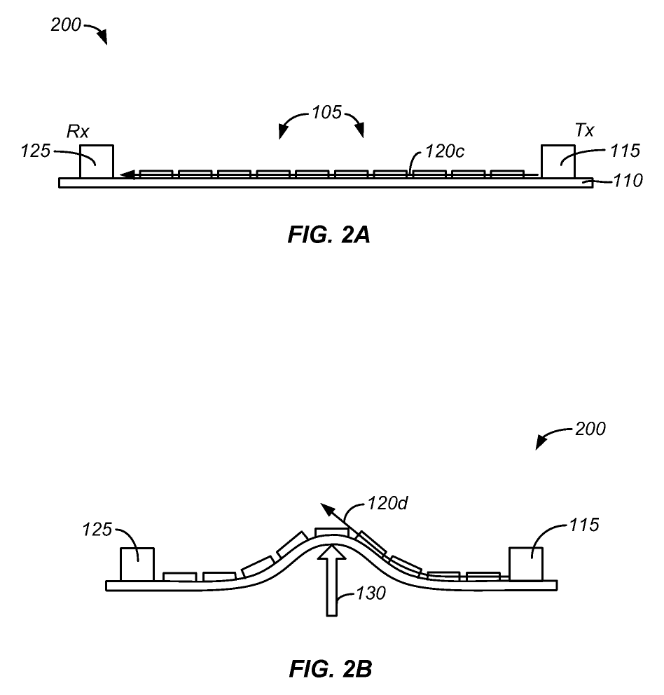

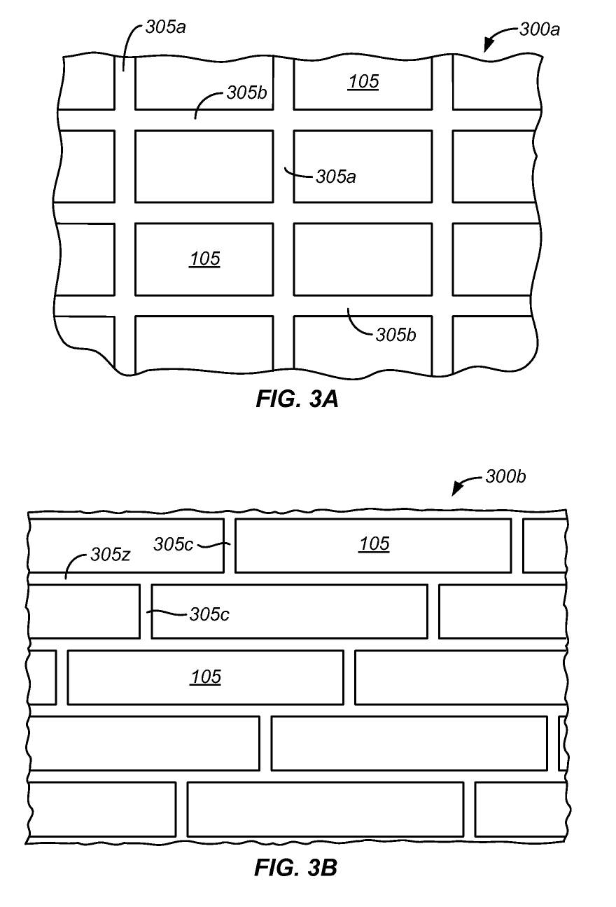

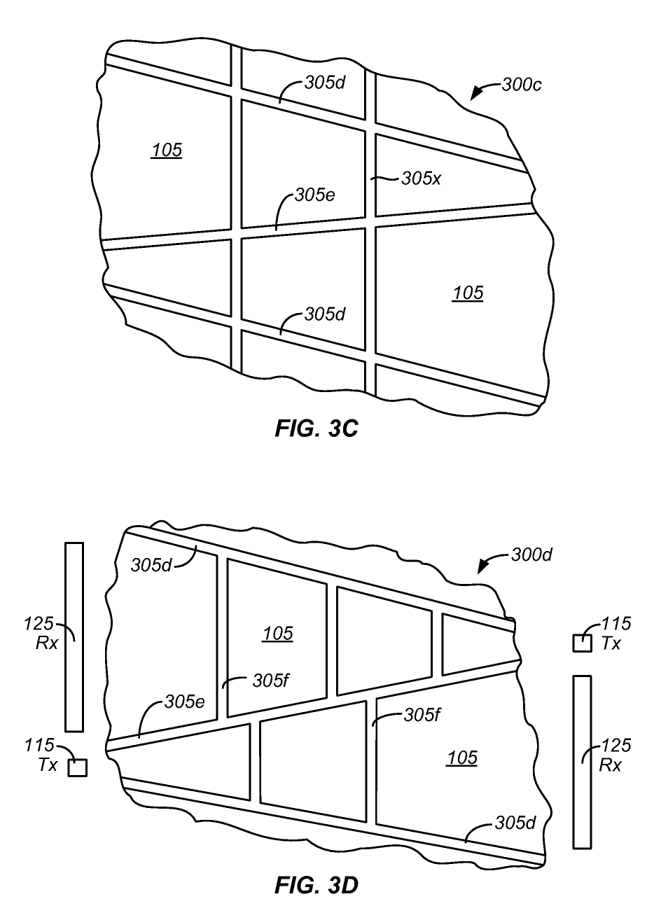

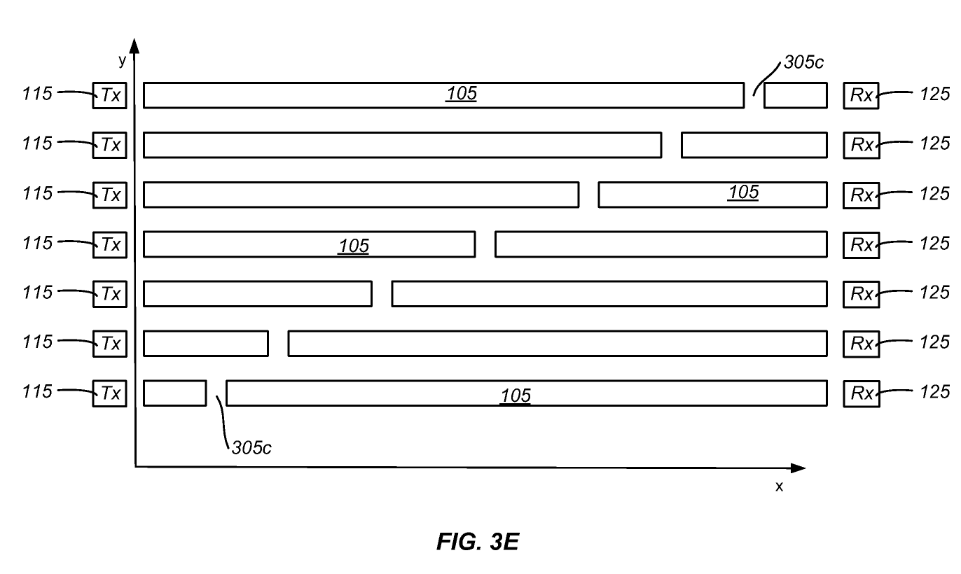

Some examples of optical interrupting interfaces will now be described. Referring first to FIG. 1A, a cross-section of a simplified optical interrupting interface 100 will be described. Optical interrupting interface 100 comprises adjacent waveguide features 105a and 105b (collectively referred to as waveguide features 105) on a flexible substrate 110. The cross-section of FIG. 1A has been made along an arbitrary line; optical interrupting interface 100 may be envisioned as extending both into and out of the page. In practice, an optical interrupting interface 100 may comprise a light-transmitting layer formed from a larger number of waveguide features 105 than the two depicted in FIG. 1A. Moreover, the light-transmitting layer formed from these waveguide features 105 may have gaps in other locations, e.g., as described below with reference to FIGS. 2A, 2B and 3A through 3D. However, the simplified version depicted in FIG. 1A is useful for illustrating and describing some basic concepts of operation.

Many types of waveguide features 105 may be used to implement the optical interrupting interfaces described herein. Although waveguide features 105 may be formed of various materials, waveguide features 105 will generally include a “high index” material having a relatively higher index of refraction disposed between “low index” materials having a relatively lower index of refraction. The terms “high index” and “low index” are intended to mean a relatively high or low index of refraction as compared to that of other materials described herein. Such terms do not necessarily mean, for example, that the “high index” material has an index of refraction that is above a predetermined threshold level.

The high index material may comprise, for example, a dielectric material such as glass, polycarbonate, polystyrene, polyethylene terephthalate (“PET”), polyimide, or other suitable material(s). The low index materials may, for example, comprise glass, plastic, a polymer (e.g., such as polycarbonate), poly(methyl methacrylate) (“PMMA”), etc. In some implementations, one or more of the low index layers may comprise air.

Flexible substrate 110 may comprise, for example, an elastic polymer or “elastomer” such as natural or synthetic rubber (saturated or unsaturated), a thermoplastic elastomer (“TPE”) such as Elastron®, a thermoplastic vulcanizate (“TPV”) such as Santoprene™ TPV, a thermoplastic polyurethane (“TPU”), a thermoplastic olefin (“TPO”), resilin, elastin, etc. In some implementations, flexible substrate 110 may comprise a low index material and/or waveguide features 105 may be attached to flexible substrate 110 with a low index bonding material. The latter may be advantageous when, for example, a waveguide is attached to a flexible substrate having an index of refraction higher than that of the waveguide.

Moreover, various shapes and configurations of waveguide features 105 are contemplated by the inventor. In some embodiments, waveguide features 105 may comprise various shapes formed from blocks or slabs of waveguide material. Some example shapes are provided in FIGS. 3A through 3D. In some embodiments, waveguide features 105 may comprise optical fiber. Although optical fiber is typically circular in cross-section, other shapes and configurations may be used. In some embodiments, waveguide features 105 may comprise a film with embedded segments of optical fiber.

In some embodiments, transmitter 115 may produce light itself, whereas in other embodiments transmitter 115 may conduct light from another light source. In one example of the latter configuration, transmitter 115 may comprise a waveguide such as an optical fiber that is configured to conduct light from another light source and to provide light to waveguide feature 105a. The light source may be any convenient light source, e.g., a light-emitting diode (“LED”). Similarly, in some embodiments receiver 125 may be configured to detect light, whereas in other embodiments receiver 125 may be configured to conduct light from waveguide feature 105b to a light detector. In one example, receiver 125 may comprise a waveguide such as an optical fiber that is configured to conduct light from waveguide feature 105b to a light detector.

Although only a single transmitter 115 and a single receiver 125 are depicted, some implementations include a plurality of transmitters 115 and receivers 125. These may be disposed on the sides shown, disposed on other sides (e.g., on sides that are out of the plane of FIG. 1A), or disposed in any convenient fashion.

The embodiments described herein may involve a one-to-one, a one-to-many or a many-to-one relationship between light sources, transmitters, waveguide features, receivers and/or light detectors. In some embodiments, a plurality of transmitters may convey light from a single light source to a plurality of waveguide features 105, e.g., via optical fibers. Similarly, a plurality of receivers may convey light from a plurality of waveguide features 105 to single detector. However, in alternative embodiments, a plurality of transmitters may convey light to a single waveguide feature. In some such embodiments, each of the plurality of transmitters may convey light having a different range of wavelengths. In some embodiments, a plurality of receivers may convey light from a single waveguide feature to a plurality of light detectors. In yet other embodiments, a first transmitter may convey light having a first range of wavelengths to a first waveguide feature, whereas a second transmitter may convey light having a different range of wavelengths to a second waveguide feature. In some implementations, the arrangement of transmitters 115 and receivers 125 may depend, at least in part, on the arrangement of waveguide features 105. Some examples are described below with reference to FIGS. 3C and 3D.

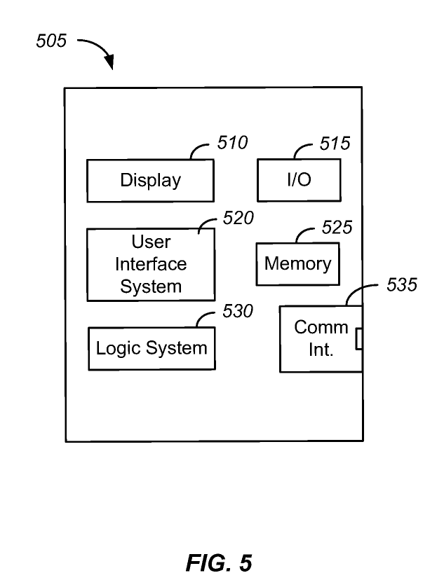

The light source(s) and light detector(s) are configured for communication with a logic system. Although this logic system is not shown in FIGS. 1A or 1B, an example is shown and described below with reference to FIG. 5. Such a logic system may include one or more logic devices, such as processors, programmable logic devices, etc.

As depicted in FIG. 1A, whatever the materials and shapes of waveguide features 105, they may be part of a light-transmitting layer that is configured to allow light 120a to propagate from transmitter 115 through waveguide features 105a and 105b to receiver 125, at least while flexible material 110 is in an un-deformed condition or while the light is not being obstructed for some other reason, e.g., as described below. (“Light” as used herein may include, but is not limited to, electromagnetic radiation that is visible to human beings.)

As shown in FIG. 1B, if a sufficiently large force 130 is applied to flexible material 110 at least some of the light 120b that has propagated from transmitter 115 and through waveguide feature 105a may not reach 105b or receiver 125. Based on input received from a plurality of detectors 125, a logic system may be configured to determine an area of the light-transmitting layer that is transmitting less light (or that is not transmitting light) between at least two adjacent waveguide features. In some implementations, the logic system may have been previously calibrated, at least in part, with reference to patterns and amounts of light received by receivers 125 when known areas of the light-transmitting layer are deformed by force 130. In some such implementations, a calibration algorithm for resistive-type touch screens may be used to calibrate the logic system.

The logic system may be further configured to determine a magnitude of the force and/or a time interval during which the force is applied. For example, forces of known magnitude may be applied to various locations of the optical interrupting interface. A resulting pattern of non-transmission and reduced transmission may be recorded and associated with each known force at each known location. A given force, for example, may correspond with an area over which light is not being transmitted and a surrounding area in which transmission has decreased. A smaller force may result in a diminution of transmitted light in an observed area, without producing an area over which light is not being transmitted. The resulting data may be observed and recorded. In such a manner, the responses of known forces applied to known areas may be determined and stored for future reference.

In a similar fashion, the logic system may be configured to determine when an applied force is above a predetermined threshold force. The logic system may be configured to associate an area of the optical interrupting interface, a force's magnitude, and/or a force's duration with a predetermined user input, e.g., a user instruction. As described in more detail elsewhere herein, the logic system may correlate a “squeeze” of the optical interrupting interface, a finger's trace along the optical interrupting interface and/or other predetermined actions with user instructions.

FIGS. 2A and 2B depict cross sections through a more complex optical interrupting interface 200. When light 120 traverses optical interrupting interface 200, light 120 is transmitted through multiple waveguide features 105 and across multiple gaps. A light-transmitting layer formed from multiple waveguide features 105 may have gaps in other locations than are depicted in FIGS. 2A and 2B, e.g., as shown in FIGS. 3A through 3D. For example, there may also be gaps between waveguide features 105 along an axis that extends through the plane depicted by the cross-section of FIGS. 2A and 2B. In such implementations, the light-transmitting layer formed from these multiple waveguide features 105 may be considered an optical sheet that has been cut into an array of blocks. These blocks, which correspond to waveguide features 105, may or may not be uniform in shape. Moreover, waveguide features 105 may or may not be distributed in a uniform pattern on flexible layer 110.

When force 130 is applied to optical interrupting interface 200 (see FIG. 2B), the force's attributes (e.g., location, magnitude, time duration) may be determined according to localized decreases in the transmitted light. When force 130 is above a certain magnitude, at least some of light 120d may not be transmitted between adjacent waveguide features 105. Having a relatively larger number of gaps between waveguide features 105 and interstitial gaps allows for a relatively more precise determination of the force's attributes, including but not limited to a relatively more precise determination of the location at which force 130 is applied. Such configurations may be useful for sensing touches and other physical loads whether the flexible substrate is applied to a flat surface or to a more complex shape.

It will be appreciated that various types of forces and stresses will cause corresponding areas of optical interrupting interface 200 to experience a localized reduction in light transmission and/or a localized area of non-transmission. For example, a user's squeeze may be detected as a fold along which light transmission decreases or ceases. In some implementations, the amount of force applied during the squeeze, the duration of the squeeze and/or a sequence of squeezes may correspond with predetermined user instructions for an associated device.

FIGS. 3A through 3E illustrate examples of various ways in which waveguide features 105 may be distributed on flexible layer 110. In the example depicted in FIG. 3A, waveguide features 105 are distributed in a substantially uniform pattern on flexible layer 110 and are substantially uniform in shape. In this example, gaps 305a are substantially parallel to each other and are substantially perpendicular to gaps 305b. Moreover, gaps 305a between waveguide features 105 in a first row are collinear with gaps 305a between waveguide features 105 in an adjacent row. Such an arrangement may make it relatively easier to bend optical interrupting interface 300a along gaps 305a and 305b, as compared to other arrangements described herein. However, this will depend in part on the thickness and bulk modulus of the flexible layer 110.

In the embodiment depicted in FIG. 3B, waveguide features 105 are distributed in a substantially uniform pattern on flexible layer 110 and are substantially uniform in shape. In this example, however, waveguide features 105 have a different aspect ratio and are distributed in a different pattern on flexible layer 110: here, gaps 305c are offset from one another, whereas gaps 305z are substantially continuous. Such an arrangement may allow more precise locations of forces that are applied to optical interrupting interface 300b. For example, gaps 305z of optical interrupting interface 300b are more closely spaced than gaps 305b of optical interrupting interface 300a. Moreover, optical interrupting interface 300b may bend more easily along different axes (e.g., non-vertical axes) than optical interrupting interface 300a would.

In the embodiment depicted in FIG. 3C, waveguide features 105 are not uniform in shape. In this example, waveguide features 105 are formed in trapezoids of various sizes and shapes. In this example, gaps 305x are parallel to one another and collinear. Gaps 305d are substantially parallel to one another, but are not parallel to gaps 305e. Neither gaps 305d nor gaps 305e are substantially perpendicular to gaps 305x.

The waveguide features 105 depicted in the embodiment shown in FIG. 3D are also non-uniform in shape. Waveguide features 105 are once again formed in trapezoids of various sizes and shapes. In this example, gaps 305f are parallel to one another but are offset from one another. Gaps 305d are substantially parallel to one another, but are not parallel to gaps 305e. Neither gaps 305d nor gaps 305e are substantially perpendicular to gaps 305f. In this example, the placement and extent of transmitters 115 and receivers 125 corresponds with the layout of waveguide features 105: the arrangement of receivers 125 takes into account expected beam divergence of light transmitted across optical interrupting interface 300d.

Optical interrupting interfaces and their components may have a wide variety of configurations and form factors. FIG. 3E provides another example. Here, waveguide features 105 are generally rectangular in shape, but have varying lengths. In this example, gaps 305c between adjacent waveguide features 105 are disposed at varying distances from transmitters 115 and receivers 125, as measured in the x direction. Such a configuration may be advantageous, e.g., for optical interrupting interfaces having a form factor in which the length (as measured along the x axis) is substantially greater than the width (as measured along the y axis).

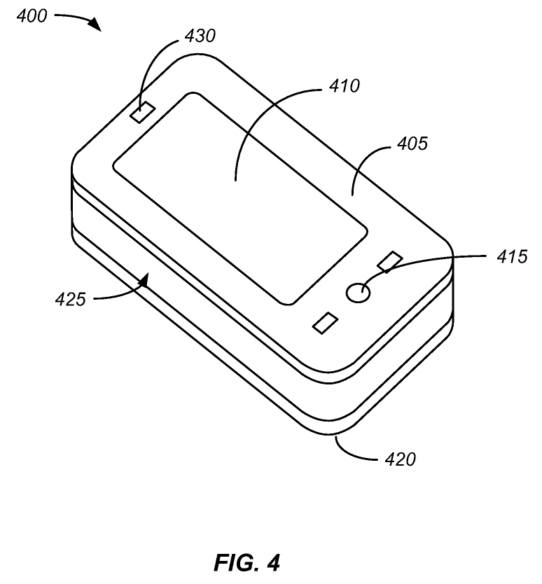

Referring now to FIG. 4, one example of a device that incorporates one or more optical interrupting interfaces will now be described. In this example, device 400 comprises display 410 and a relatively rigid face 405. The back of device 400 and lip 420 are also relatively rigid. Here, the user interface system of device 400 includes trackball 415 and one or more optical interrupting interfaces disposed in one or more flexible sides 425. In some implementations, the optical interrupting interfaces disposed in flexible sides 425 may be of the general type depicted in FIG. 3E. However, other implementations of device 400 may incorporate configurations of optical interrupting interfaces.

The user interface system may include other components of device 400, e.g., if display 410 is a touch screen display. A logic system of the device may use detected characteristics of optical transmission of the optical interrupting interface(s) to determine various types of force attributes.

For example, the logic system may determine one or more of the following:

Where is the device being squeezed?

How hard is the device being squeezed?

How rapidly is the device being squeezed and/or released?

At how many different places is the device being squeezed?

A logic system of the device may correlate each type of squeeze, as well as other applied forces and user actions, with user input. Accordingly, a new form of user interface can be created by detecting, interpreting and responding to these user actions.

For example, suppose that device 400 is a cellular telephone, a personal digital assistant with telephonic functions, etc. One soft squeeze while device 400 is ringing may correlate with a user instruction, e.g., for device 400 to provide audio caller ID information via speaker 430. A subsequent hard squeeze may correspond with another user instruction, e.g., to pick up the current call. A brush along one of flexible sides 425 may correspond with another instruction, e.g., to cause an email to be read by device 400 via speaker 430.

Various other forces, force characteristics and combinations thereof may correspond with user instructions. For example, a first set of instructions may be enabled for the optical interrupting interface(s) when another user interface is in a first position, e.g., when a key is pressed, when trackball 415 is rolled in a predetermined direction, when an area of a touch-sensitive display is touched, etc. A second set of instructions may be enabled for the optical interrupting interface(s) when the user interface (or another user interface) is in a second position, and so on.

Accordingly, a new type of gesture interface is enabled by various implementations described herein and their equivalents. Such gesture interfaces do not necessarily involve a user's gestures in the air, but may involve other types of gestures and motions, e.g., gestures along the edges of a device, squeezing a device, etc. These devices are amenable to many different kinds of industrial design, many different configurations of the optical interrupting interface(s) and/or many different manners of incorporating the functionality of the optical interrupting interface(s) with other user interfaces.

Accordingly, optical interrupting interfaces may be incorporated into many types of devices. Referring now to FIG. 5, a schematic diagram that includes components of a device 505 will now be described. In this example, user interface system 520 comprises at least one optical interrupting interface. Device 505 includes a display 510, which may be any convenient type of display. In some implementations, display 510 comprises a touch screen and may be considered part of user interface system 520. In this example, device 505 is a portable communication device that includes a communication interface 535, which may be any convenient type of communication interface. Device 505 may also include one or more microphones, speakers, etc. (not shown).

Input/output (“I/O”) system 515 may be any convenient system for communication between the various components of device 505, including communication interface 535, logic system 530, memory system 525, user interface system 520, display system 510, etc. In some implementations, I/O system 515 may comprise a bus-based system. In other implementations, I/O system 515 may comprise a point-to-point system.

Logic system 530 may include one or more logic devices, such as processors, programmable logic devices, etc, used for the operation of device 505. Logic system 530 may, for example, provide signals to display 510 and/or communication interface system 535 according to input received from user interface system 520.

Logic system 530 may be configured to determine at least one portion of the optical interrupting interface to which a force is being applied. Logic system 530 may be further configured to determine a magnitude of the force and/or a time interval during which a force is applied to an optical interrupting interface. Logic system 530 may be configured to determine when an applied force is above a predetermined threshold force. Logic system 530 may be further configured to associate an area of the optical interrupting interface, a force magnitude, a force duration, etc., with a predetermined user instructions or other input, e.g., as described elsewhere herein. The associations may be made, for example, by reference to one or more data structures stored in memory 525.

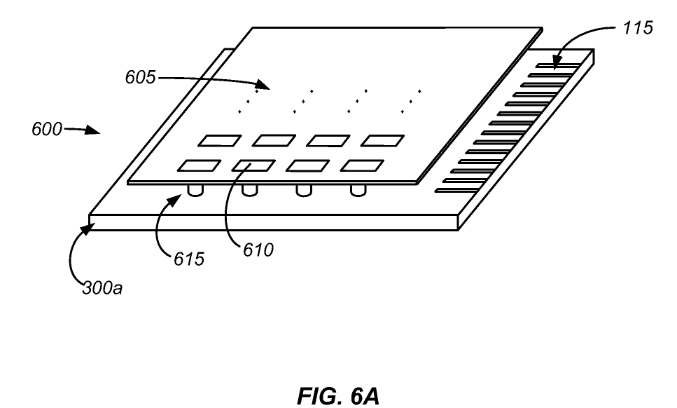

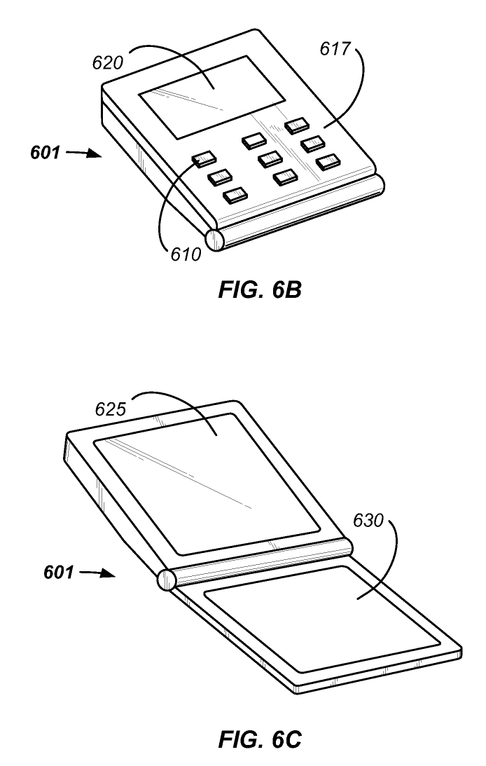

Another embodiment is depicted in FIG. 6A. Device 600 comprises an optical interrupting interface (in this example, optical interrupting interface 300a) disposed below keypad 605. Depressing one of the individual keys 610 causes one of pins 615 to contact the surface of optical interrupting interface 300a at a predictable location. This contact alters the transmission of light from transmitters 115 through optical interrupting interface 300a in the vicinity of the predictable location. In some implementations, the transmission of light may be decreased by distorting the optical interrupting interface 300a, e.g., as described above.

However, in alternative implementations, the transmission of light may be interrupted (or at least reduced) without requiring the optical interrupting interface 300a to be distorted. For example, pins 615 may be configured to fit into holes or gaps in the optical interrupting interface 300a. In some such implementations, pins 615 may be configured to fit into gaps 305a and/or 305b (see FIG. 3A), thereby blocking at least some of the light transmitted between adjacent waveguide features 105. Optical interrupting interface 300a may or may not be distorted by the action of pins 615, according to the implementation. Accordingly, the transmission of light may be decreased without requiring optical interrupting interface 300a to be distorted.

Such embodiments can provide full keyboard functionality, including the feel of individual keys being depressed. This feeling is desired by many users and is not provided by, e.g., a keypad provided on a touch screen. Some embodiments may also provide a clicking sound when keys of keypad 605 are depressed. These sounds may be caused by the mechanism of keypad 605 itself and/or provided by reproducing recorded keyboard clicks via one or more speakers. Alternative implementations may provide tactile feedback corresponding to the use of keypad 605 through the use of vibrational devices and/or piezoelectric devices, thus providing a haptic interface.

Alternative embodiments similar to device 600 may be useful, e.g., in a clamshell or flip-phone type configuration. Some such examples will now be described with reference to FIGS. 6B and 6C. Referring first to FIG. 6B, portable device 601 is first shown in a closed configuration. Portable device 601 may include a communication interface system, logic system, memory, etc., for example as described above with reference to FIG. 5. In this example, portable device 601 includes keys 610 disposed on outer surface 617. When keys 610 are pressed, at least some of the light passing through an optical interrupting interface (disposed below keys 610) is interrupted. Light may be interrupted with or without distortion of the optical interrupting interface, e.g., as described above with reference to FIG. 6A. In either type of implementation, external keypad capability can be provided without the need to route an electrical connection to the area of the keypad itself. In this example, pressing one of keys 610 causes distortion of the optical interrupting interface.

In the embodiment shown in FIG. 6B, nine keys 610 are provided on outer surface 617. Alternative embodiments may include more or fewer keys 610. Moreover, the functionality enabled by keys 610 may vary according to the implementation. For example, if portable device 601 is configured for use as a portable telephone, keys 610 may enable telephone-related features, e.g., send call to voicemail, dial a programmed number, enable headset functionality, etc. If portable device 601 is configured for use as a navigation device (e.g., a Global Positioning System [“GPS”] device), keys 610 may enable navigation-related features, e.g., enable directions by voice, enable voice control of device, etc.

Although convenient, exterior buttons could be inadvertently activated. In some implementations, exterior button functionality is not always enabled. For example, exterior button functionality may be enabled by a predetermined combination of key strokes or by another type of user input. In this example, display 620 is a conventional display such as that currently provided on cellular telephones. However, in alternative implementations, display 620 may comprise an optical interrupting interface, a mirasol™ display, etc.

Referring now to FIG. 6C, portable device 601 is shown in an opened condition. In this example, user interface 630 provides a user access to the same optical interrupting interface that is used in connection with keys 610. In some embodiments, a logic system of portable device 601 interprets signals from the optical interrupting interface in a different manner according to whether portable device 601 is open or closed. This may be advantageous, for example, because a user may distort the optical interrupting interface inward when pressing on keys 610, but will distort the optical interrupting interface in the opposite direction (here, outward) when pressing on user interface 630. In some such implementations, the logic system will determine whether portable device 601 is open or closed and will apply different algorithms and/or rule sets to interpret light transmission of the optical interrupting interface for the two cases of operation.

In some embodiments, user interface 630 provides additional functionality as compared to that provided by buttons 610. For example, if portable device 601 is configured for use as a navigation device, user interface 630 may allow a user to control navigation data presented on display 625 and/or on user interface 630. User interface 630 may allow a user to zoom in, zoom out, select a map view, select a satellite view, etc. In alternative embodiments, user interface 630 may provide a larger number of keys than are provided on outer surface 615, e.g., 30 keys, an entire QWERTY keyboard, etc. If so, the keys may be physical keys such as “chicklets” or designated areas of a screen. In some implementations, user interface 630 may comprise a touch screen with no symbology.

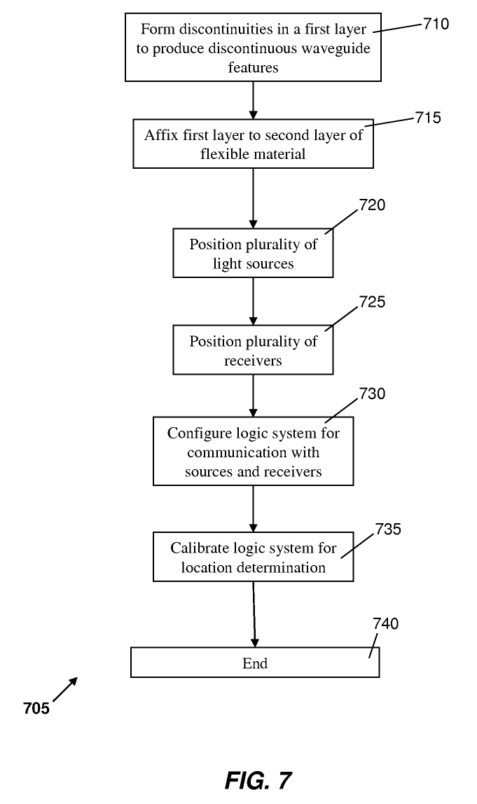

Referring now to FIG. 7, a process of fabricating an optical interrupting interface will now be described. The steps of process 705 are not necessarily performed in the order indicated. Moreover, process 705 may include more or fewer steps than are indicated. In some implementations, the steps described as separate steps of process 705 may be combined. Conversely, what may be described as a single step of process 705 may be implemented in multiple steps.

In step 710, discontinuities are formed in a waveguide layer, thereby forming a layer of discontinuous waveguide features. The waveguide layer may, for example, comprise a layer of high index material sandwiched between layers of low index material. In some embodiments, the waveguide layer may comprise a film with embedded segments of optical fiber. The process of forming discontinuities may involve an etching process, a dicing process, an embossing process, a stamping process, or any other convenient process. In some implementations, the process will be part of a roll-to-roll process.

In this example, the layer of discontinuous waveguide features is then affixed to a layer of flexible material. (Step 715.) However, in alternative implementations, the waveguide layer is affixed to the flexible layer before the discontinuities are formed. Such alternative implementations may allow for relatively more precise positioning of the discontinuous waveguide features on the flexible layer.

In step 720, a plurality of light sources is positioned such that they can provide light to various parts of the layer of discontinuous waveguide features. A plurality of receivers is positioned such that they can receive light from various parts of the layer of discontinuous waveguide features. (Step 725.) A logic system, which may include one or more logic devices (such as processors, programmable logic devices, etc.) is configured for communication with the sources and receivers.

The logic system is then calibrated. For example, the logic system may be calibrated with reference to patterns and amounts of light received by the receivers when known forces are applied to known areas of the layer of flexible material. In some implementations, a calibration algorithm for resistive-type touch screens may be used to calibrate the logic system. The logic system may be further configured to determine a magnitude of the force and/or a time interval during which the force is applied. In a similar fashion, the logic system may be configured to determine when an applied force is above a predetermined threshold force.

The resulting data may be observed and recorded. In such a manner, the responses of known forces applied to known areas may be determined and stored for future reference.

The logic system may also be configured to associate an area of the optical interrupting interface, a force's magnitude, and/or a force's duration with a predetermined user input, e.g., a user instruction. The logic system may be configured to correlate a “squeeze” of the optical interrupting interface, a finger's trace along the optical interrupting interface and/or other predetermined actions with user instructions. In this example, process 705 ends when the calibration process is complete. (Step 740.)

Although illustrative embodiments and applications of this invention are shown and described herein, many variations and modifications are possible which remain within the concept, scope, and spirit of the invention, and these variations should become clear after perusal of this application. Accordingly, the present embodiments are to be considered as illustrative and not restrictive, and the invention is not to be limited to the details given herein, but may be modified within the scope and equivalents of the appended claims.

I claim:

1 An apparatus, comprising:
a flexible layer;
a light-transmitting layer affixed to the flexible layer, the light-transmitting layer comprising a plurality of discontinuous waveguide features;
at least one light source configured to provide light to the light-transmitting layer;
at least one receiver configured to receive light via the light-transmitting layer; and
a logic system configured to determine an area of the light-transmitting layer having diminished light transmission between at least two adjacent waveguide features.

2. The apparatus of claim 1, wherein a plurality of light sources is configured to provide light to the light-transmitting layer.

3. The apparatus of claim 1, wherein a plurality of receivers is configured to receive light via the light-transmitting layer.

4. A user interface comprising the apparatus of claim 1.

5. A touch screen comprising the apparatus of claim 1.

6. The apparatus of claim 1, wherein the area of the light-transmitting layer comprises a waveguide feature that has been temporarily rotated with respect to an adjacent waveguide feature.

7. The apparatus of claim 1, wherein the plurality of light sources is disposed proximate a first edge of the light-transmitting layer and wherein the plurality of receivers is disposed proximate a second edge of the light-transmitting layer.

8. A portable device comprising at least one user interface as recited in claim 4.

9. A keyboard comprising at least one user interface as recited in claim 4.

10. The apparatus of claim 6, wherein the waveguide feature has been temporarily rotated in response to a force applied to the flexible layer.

11. The portable device of claim 8, wherein at least a first user interface is disposed along a first side of the portable device.

12. A portable device that comprises the keyboard as recited in claim 9.

13. The portable device of claim 11, wherein at least a second user interface is disposed along a second side of the portable device.

14. The portable device of claim 11, wherein the logic system is further configured to determine at least one portion of the portable device to which a compressional force is being applied.

15. The portable device of claim 13, wherein the second side is opposite the first side.

16. The portable device of claim 14, wherein the logic system is further configured to determine at least one of a magnitude of the force or a time interval during which the force is applied.

17. The portable device of claim 14, wherein the logic system is configured to associate a force with a predetermined user input.

18. The portable device of claim 14, wherein the logic system is configured to associate at least one of the magnitude or the time interval with a predetermined user input.

19. A method of forming a waveguide, comprising:
forming discontinuities in a waveguide layer to produce a layer of discontinuous waveguide features;
affixing the first layer to a second layer of flexible material;
configuring at least one light source to provide light to the layer of discontinuous waveguide features;
configuring at least one receiver to receive light via the layer of discontinuous waveguide features;
configuring a logic system to do the following:
control the light source;
receive signals from the receiver; and
make a correspondence between forces applied to the flexible layer and changes of light transmission in the layer of discontinuous waveguide features.

20. The method of claim 19, wherein the step of configuring at least one light source comprises configuring a plurality of light sources to provide light to the layer of discontinuous waveguide features and wherein the controlling step comprises controlling the plurality of light sources.

21. The method of claim 19, wherein the step of configuring at least one receiver comprises configuring a plurality of receivers to provide light to the layer of discontinuous waveguide features and wherein the receiving step comprises receiving signals from the plurality of receivers.

22. The method of claim 19, wherein the forming comprises embossing, pressing or stamping.

23. The method of claim 19, wherein at least one of the forming, affixing or cladding is performed as part of a roll-to-roll process.

24. The method of claim 19, wherein the forming comprises forming linear discontinuities.

25. The method of claim 19, wherein the forming comprises forming a plurality of discontinuous polygons.

26. The method of claim 19, wherein the affixing is performed prior to the forming.

27. The method of claim 24, wherein the forming comprises forming offsets in at least some of the linear discontinuities.

28. The method of claim 26, wherein the forming comprises dicing the discontinuities into the first layer.

29. An apparatus, comprising:
a flexible layer;
a light-transmitting layer affixed to the flexible layer, the light-transmitting layer comprising a plurality of discontinuous waveguide features;
at least one light source configured to provide light to the light-transmitting layer;
at least one receiver configured to receive light via the light-transmitting layer; and
a logic system configured to determine an area of the light-transmitting layer wherein a waveguide feature has been temporarily rotated with respect to an adjacent waveguide feature.

30. The apparatus of claim 29, wherein a plurality of light sources is configured to provide light to the light-transmitting layer.

31. The apparatus of claim 29, wherein a plurality of receivers is configured to receive light via the light-transmitting layer.

32. The apparatus of claim 29, wherein the waveguide feature has been temporarily rotated by a force that has been applied to the flexible layer.

33. The apparatus of claim 29, wherein the waveguide features are polygonal in shape.

34. The apparatus of claim 29, wherein the waveguide features are rectangular in shape.

35. A portable device, comprising:
a flexible layer;
a light-transmitting layer affixed to the flexible layer, the light-transmitting layer comprising a plurality of discontinuous waveguide features;
at least one light source configured to provide light to the light-transmitting layer;
at least one receiver configured to receive light via the light-transmitting layer;
a logic system configured to determine an area of the light-transmitting layer having diminished light transmission between at least two adjacent waveguide features; and
at least one key disposed on a first surface of the portable device and configured to cause diminished light transmission between at least two adjacent waveguide features when depressed.

36. The portable device of claim 35, further comprising a plurality of light sources configured to provide light to the light-transmitting layer.

37. The portable device of claim 35, further comprising a plurality of receivers configured to receive light via the light-transmitting layer.

38. The portable device of claim 35, wherein the first surface comprises an outer surface of the portable device.

39. The portable device of claim 35, further comprising a communication interface.

40. The portable device of claim 35, further comprising a user interface disposed on a second surface of the portable device, at least a portion of the second surface being opposite the first surface, the user interface configured to cause diminished light transmission between at least two adjacent waveguide features when depressed.

41. The portable device of claim 40, wherein the second surface comprises an inner surface of the portable device.

42. The portable device of claim 40, wherein the second surface is accessible only when the portable device is in an open position.

43. The portable device of claim 42, wherein the logic device is configured to apply a first rule set to interpret light transmission of the light-transmitting layer when the portable device is in the open position.

44. The portable device of claim 43, wherein the logic device is configured to apply a second rule set to interpret light transmission of the light-transmitting layer when the portable device is in a closed position.
